(19) United States
(12) Patent Application Publication
(10) Pub. No.: US 2025/0185420 A1
(43) Pub. Date: Jun. 5, 2025

(54) SEMICONDUCTOR LIGHT-EMITTING DEVICES AND METHODS OF MANUFACTURING THE SAME

(71) Applicant: SAMSUNG ELECTRONICS CO., LTD., Suwon-si (KR)

(72) Inventors: Donggu KIM, Suwon-si (KR); Chulmin KIM, Suwon-si (KR); Doyoung RHEE, Suwon-si (KR)

(73) Assignee: SAMSUNG ELECTRONICS CO., LTD., Suwon-si (KR)

(21) Appl. No.: 18/941,774

(22) Filed: Nov. 8, 2024

(30) Foreign Application Priority Data
Dec. 1, 2023 (KR) 10-2023-0172728
Jan. 18, 2024 (KR) 10-2024-0008283

(51) Int. Cl. H01L 33/20; H01L 33/00; H01L 33/12; H01L 33/32

(52) U.S. Cl. CPC H10H 20/819; H10H 20/01335; H10H 20/815; H10H 20/825

(57) ABSTRACT

A semiconductor light-emitting device includes a substrate including a first material, a plurality of protrusions, a buffer layer on the substrate and the plurality of protrusions, an intermediate layer on the buffer layer, and a light-emitting stacked body on the intermediate layer. Each protrusion of the plurality of protrusions includes a lower pattern including a same material as the first material of the substrate, and a feature pattern disposed on the lower pattern and including a second material different from the first material of the substrate. The intermediate layer includes silicon nitride (SiN).

### CROSS-REFERENCE TO RELATED APPLICATIONS

This application claims benefit of priority under 35 U.S.C. § 119 to Korean Patent Application No. 10-2023-0172728, filed on Dec. 1, 2023, and Korean Patent Application No. 10-2024-0008283, filed on Jan. 18, 2024, in the Korean Intellectual Property Office, the disclosures of which are incorporated by reference herein in their entireties.

### BACKGROUND

### 1. Field

The present disclosure relates generally to a semiconductor light-emitting device, and more particularly, to a semiconductor light-emitting device including a feature pattern with increased light extraction efficiency.

### 2. Description of Related Art

There may be an increased demand for using semiconductor light-emitting devices in various lighting devices, such as, but not limited to, vehicle headlamps, indoor lighting fixtures, or the like. For example, an intelligent lighting system may have been proposed that may individually control light-emitting device chips to implement various lighting modes, according to surrounding situations, when using a light source module that may include the plurality of light-emitting device chips. Thus, there exists a need for further improvements in semiconductor light-emitting device technology, as the need for intelligent lighting systems may be constrained by the light extraction efficiency of the semiconductor light-emitting devices. Improvements are presented herein. These improvements may also be applicable to other light-emitting technologies.

### SUMMARY

One or more example embodiments of the present disclosure provide a semiconductor light-emitting device with increased light extraction efficiency, when compared to related semiconductor light-emitting devices.

According to an aspect of the present disclosure, a semiconductor light-emitting device includes a substrate including a first material, a plurality of protrusions, a buffer layer on the substrate and the plurality of protrusions, an intermediate layer on the buffer layer, and a light-emitting stacked body on the intermediate layer. Each protrusion of the plurality of protrusions includes a lower pattern including a same material as the first material of the substrate, and a feature pattern disposed on the lower pattern and including a second material different from the first material of the substrate. The intermediate layer includes silicon nitride (SiN).

According to an aspect of the present disclosure, a semiconductor light-emitting device includes a substrate including a first material, a plurality of protrusions, a buffer layer on the substrate and the plurality of protrusions, an intermediate layer on the buffer layer, and a light-emitting stacked body including a first conductivity type semiconductor layer, an active layer, and a second conductivity type semiconductor layer, which are sequentially disposed on the intermediate layer. Each protrusion of the plurality of protrusions includes a lower pattern including a same material as the first material of the substrate, and a feature pattern disposed on the lower pattern and including a second material different from the first material of the substrate. The intermediate layer includes silicon nitride (SiN). The feature pattern includes at least one of silicon oxide (SiOₓ), silicon oxynitride (SiOₓN_{y}), and magnesium fluoride (MgF₂).

According to an aspect of the present disclosure, a semiconductor light-emitting device includes a substrate including a first material, a plurality of protrusions, a buffer layer on the substrate and the plurality of protrusions, an intermediate layer on the buffer layer, and a light-emitting stacked body including a first conductivity type semiconductor layer, an active layer, and a second conductivity type semiconductor layer, which are sequentially disposed on the intermediate layer. Each protrusion of the plurality of protrusions includes a lower pattern including a same material as the first material of the substrate, and a feature pattern on the lower pattern and including a second material different from the first material of the substrate. The intermediate layer includes silicon nitride (SiN). The buffer layer includes at least one of aluminum nitride (AlN), gallium nitride (GaN), indium nitride (InN), indium gallium nitride (InGaN), aluminum gallium nitride (AlGaN), indium aluminum gallium nitride (InAlGaN), or aluminum indium nitride (AlInN). The feature pattern includes at least one of silicon oxide (SiOₓ), silicon oxynitride (SiOₓN_{y}), or magnesium fluoride (MgF₂). The plurality of protrusions are disposed in a hexagonal arrangement.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a cross-sectional view illustrating a semiconductor light-emitting device, according to an embodiment;

FIG. 2 is an enlarged view of a portion CX1 of FIG. 1, according to an embodiment;

FIG. 3 is a schematic plan layout diagram of protrusions of a semiconductor light-emitting device, according to an embodiment;

FIG. 4 is a cross-sectional view illustrating a semiconductor light-emitting device, according to an embodiment;

FIG. 5 is a cross-sectional view illustrating a semiconductor light-emitting device, according to an embodiment;

FIG. 6 is a cross-sectional view illustrating a semiconductor light-emitting device, according to an embodiment;

FIGS. 7 to 15 are cross-sectional views illustrating a method of manufacturing a semiconductor light-emitting device, according to an embodiment;

FIGS. 16A and 16B are scanning electron microscope (SEM) images respectively illustrating protrusions and a first-conductivity-type semiconductor layer in a crystal growth process, respectively, according to a comparative example and an example;

FIG. 17 illustrates graphs of transmission electron microscope-energy dispersive spectrometer (TEM-EDS) observation results of a semiconductor light-emitting device, according to an embodiment;

FIG. 18 is a cross-sectional view illustrating a light source module including a semiconductor light-emitting device, according to an embodiment;

FIGS. 19 to 22 are perspective views schematically illustrating lighting devices including semiconductor light-emitting devices, according to embodiments;

FIG. 23 is a schematic diagram illustrating an indoor lighting control network system including a semiconductor light-emitting device, according to an embodiment; and

FIG. 24 is a schematic diagram illustrating a network system including a semiconductor light-emitting device, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “AlGaN”, “AlₓIn_{y}Ga_{z}N”, “AlInN”, “AlN”, “Al₂O₃”, “BCl₃”, “CF₄”, “GaInO”, “GaN”, “GaN”, “InAlGaN”, “InₓAl_{y}Ga_{(1-x-y)}N”, “InGaN”, “InxGa₁₋ₓN”, “InN”, “InSnO”, “LiAlO₂”, “LiGaO₂”, “MgAl₂O₄”, “MgF₂”, “MgO”, “SF₆”, “SiC”, “SiN”, “SnO”, “SiOₓ”, “SiOₓN_{y}”, “ZnInO”, “Zn₍₁₋ₓ₎MgₓO”, “ZnSnO”, “ZnInSnO”, and the like may refer to a material made of elements included in each of the terms and is not a chemical formula representing a stoichiometric relationship.

Hereinafter, various embodiments of the present disclosure are described with reference to the accompanying drawings.

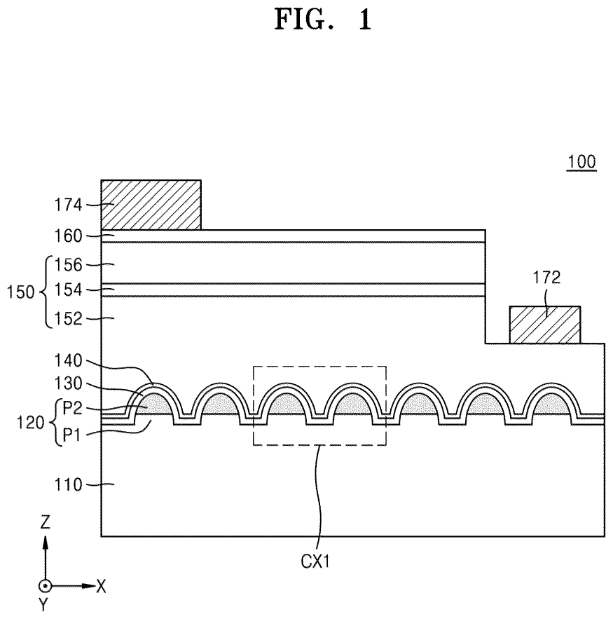

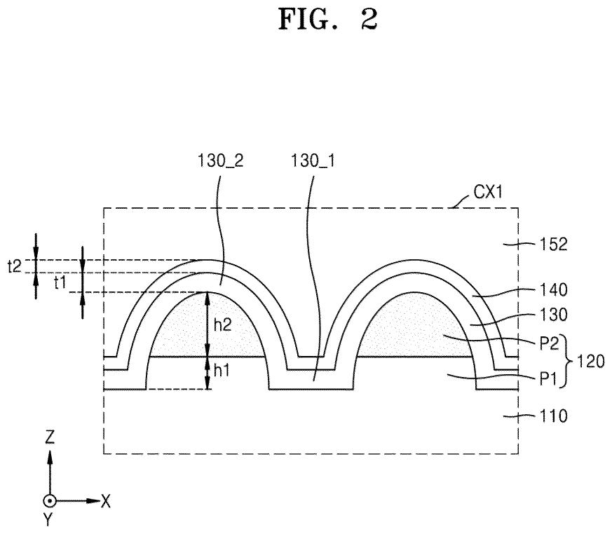

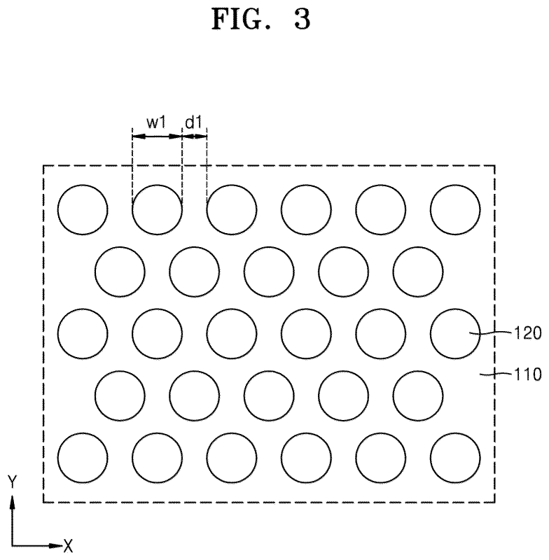

FIG. 1 is a cross-sectional view illustrating a semiconductor light-emitting device, according to an embodiment. FIG. 2 is an enlarged view of a portion CX1 of FIG. 1, according to an embodiment. FIG. 3 is a schematic plan layout diagram of protrusions of a semiconductor light-emitting device, according to an embodiment.

Referring to FIG. 1, a semiconductor light-emitting device 100 may include a substrate 110, protrusions 120, a buffer layer 130, an intermediate layer 140, a light-emitting stacked body 150, a transparent electrode layer 160, a first electrode 172, and a second electrode 174.

In some embodiments, the substrate 110 may include, but not be limited to, at least one of sapphire (Al₂O₃), silicon carbide (SiC), silicon (Si), magnesium aluminate (MgAl₂O₄), magnesium oxide (MgO), lithium aluminate (LiAlO₂), lithium gallium oxide (LiGaO₂), or gallium nitride (GaN). In some embodiments, the substrate 110 may be a transparent substrate and include, for example, sapphire (Al₂O₃).

In some embodiments, the protrusions 120 may be arranged on an upper surface of the substrate 110. The protrusions 120 may include a lower pattern P1 connected to the substrate 110 and protruding from the substrate 110, and a feature pattern P2 arranged on the lower pattern P1 and formed of a material that is different from a material of the lower pattern P1.

The lower pattern P1 may be integrally connected to the substrate 110 and may be formed of the same material as the substrate 110. For example, the lower pattern P1 may include, but not be limited to, at least one of sapphire (Al₂O₃), silicon carbide (SiC), silicon (Si), magnesium aluminate (MgAl₂O₄), magnesium oxide (MgO), lithium aluminate (LiAlO₂), lithium gallium oxide (LiGaO₂), or gallium nitride (GaN).

The lower pattern P1 may be formed by removing a part of the substrate 110. In an etching process of forming the feature pattern P2 on the substrate 110, a part of the substrate 110 may be removed together, and accordingly, a part (e.g., a part of the substrate 110 that is covered by the feature pattern P2 and remains without being removed) of the substrate 110 below the feature pattern P2 may be referred to as the lower pattern P1.

In some embodiments, the feature pattern P2 may be formed of a material with a lower refractive index than the substrate 110. In some embodiments, the feature pattern P2 may have a refractive index of 1 to 1.7. In some embodiments, the feature pattern P2 may include, but not be limited to, at least one of silicon oxide (SiOₓ), silicon oxynitride (SiOₓN_{y}), or magnesium fluoride (MgF₂).

In some embodiments, a bottom surface of the feature pattern P2 may be in contact with an upper surface of the lower pattern P1 and may have a flat profile, and a width of an upper side of the feature pattern P2 may gradually decrease from the upper surface of the lower pattern P1 toward a side surface of the lower pattern P1. In some embodiments, the feature pattern P2 may have a hemispherical shape. In some other embodiments, the feature pattern P2 may have a cone shape.

The lower pattern P1 may have a first height h1 from an upper surface of the substrate 110, and for example, the first height h1 may be in a range of about 200 nanometers (nm) to about 400 nm. However, the present disclosure is not limited in this regard, and the first height h1 may be less than 200 nm or greater than 400 nm. The first height h1 may correspond to a depth at which the substrate 110 is etched, for example, a distance in a vertical direction Z between the upper surface of the lower pattern P1 and the upper surface of the substrate 110. The feature pattern P2 may have a second height h2, and the second height h2 may be greater than the first height h1. For example, the second height h2 may be in a range of about 200 nm to about 2 micrometers (μm). However, the present disclosure is not limited in this regard, and the second height h2 may be less than 200 nm or greater than 2 μm.

In some embodiments, a ratio of the second height h2 of the feature pattern P2 to the total height of the protrusion 120 may range from about 0.5 to about 0.9. However, the present disclosure is not limited in this regard, and the ratio of the second height h2 of the feature pattern P2 to the total height of the protrusion 120 may be less than 0.5 or greater than 0.9. For example, the total height of the protrusion 120 may be the sum of the first height h1 of the lower pattern P1 and the second height h2 of the feature pattern P2, and the second height h2 of the feature pattern P2 may range from about 50% to about 90% of the total height of the protrusion 120.

In some embodiments, the protrusions 120 may be arranged at regular intervals over the entire area of the substrate 110 in a plan view. For example, as shown in FIG. 3, the protrusions 120 may be arranged in a hexagonal arrangement or a honeycomb arrangement in a plan view. Each of the protrusions 120 may have a first width w1, and the protrusions 120 may be separated from each other by a first distance d1 in a first horizontal direction X and/or in a diagonal direction. In some embodiments, the first width w1 of the protrusion 120 may range from about 200 nm to about 5 μm, and the first distance d1 may range from about 100 nm to about 5 μm. In some embodiments, the first distance d1 may be 0.5 to 10 times the first width w1. That is, a ratio of the first distance d1 to the first width w1 may be in a range of 0.5 to 10. However, the present disclosure is not limited in this regard, and the first distance d1 and the first width w1 may have other values and/or ratios than those discussed above.

The buffer layer 130 may be on an upper surface of the substrate 110 and on upper surfaces of the protrusions 120. The buffer layer 130 may be formed in a conformal shape that covers the upper surfaces of the protrusions 120 and may be formed to have a substantially uniform and/or a same thickness, for example, on a sidewall of the lower pattern P1 and an upper surface of the feature pattern P2.

The buffer layer 130 may include a first portion 130_1 having a flat upper surface on an upper surface of the substrate 110, and a second portion 130_2 that convexly protrudes and covers the upper surface of the protrusion 120. For example, the second portion 130_2 of the buffer layer 130 may be in contact with an upper surface of the feature pattern P2 and a sidewall of the lower pattern P1.

In some embodiments, the buffer layer 130 may include, but not be limited to, at least one of aluminum nitride (AlN), gallium nitride (GaN), indium nitride (InN), indium gallium nitride (InGaN), aluminum gallium nitride (AlGaN), indium aluminum gallium nitride (InAlGaN), and aluminum indium nitride (AlInN). The buffer layer 130 may have a first thickness t1, and for example, the first thickness t1 may be in a range of about 5 nm to about 30 nm. However, the present disclosure is not limited in this regard, and the first thickness t1 may be less than 5 nm or greater than 30 nm. In some embodiments, the buffer layer 130 may be formed at a temperature of about 500 degrees Celsius (° C.) to about 600° C. and may include a plurality of layers having different compositions.

The intermediate layer 140 may be on the buffer layer 130. The intermediate layer 140 may be conformally arranged on an upper surface of the substrate 110 and on upper surfaces of the protrusions 120. In some embodiments, the intermediate layer 140 may include, but not be limited to, silicon nitride (SiN). For example, the intermediate layer 140 may have a second thickness t2, and the second thickness t2 may range from about 1 angstrom (A) to about 1 nm. However, the present disclosure is not limited in this regard, and the second thickness t2 may be less than 1 Å or greater than 1 nm.

In some embodiments, the intermediate layer 140 may be formed by forming a monolayer on a surface of the buffer layer 130 or forming five (5) or less material layers (e.g., five (5) or less monolayers) through an atomic layer deposition (ALD) process. In some embodiments, the intermediate layer 140 may be formed by forming ten (10) or less material layers (e.g., ten (10) or less monolayers) on a surface of the buffer layer 130 through an ALD process. In some embodiments, a monolayer of silicon nitride (SiN) may be formed by continuously supplying a silicon (Si) precursor, purging the silicon (Si) precursor, supplying a reactant including nitrogen (N), and purging the reactant in the ALD process. In some embodiments, the intermediate layer 140 may be formed by repeating several to dozens of times a unit deposition cycle consisting of supplying a silicon (Si) precursor, purging the silicon (Si) precursor, supplying a reactant including nitrogen (N), and purging the reactant.

In some embodiments, when the intermediate layer 140 is formed to have a relatively small second thickness t2, the intermediate layer 140 may not be clearly identified by observation tools, such as, but not limited to, a scanning electron microscope (SEM) or a transmission electron microscope (TEM). For example, an interface between the intermediate layer 140 and the buffer layer 130 and/or an interface between the intermediate layer 140 and the light-emitting stacked body 150 may not be clearly identified. However, in such a case, the presence of silicon (Si) atoms and nitrogen (N) atoms included in the intermediate layer 140 may be checked by an analysis tool, such as, but not limited to, a transmission electron microscope-energy dispersive spectrometer (TEM-EDS), a SEM-energy dispersive spectrometer (SEM-EDS), or a secondary ion mass spectrometry (SIMS).

In some embodiments, the light-emitting stacked body 150 on the intermediate layer 140 may cover the protrusions 120. The light-emitting stacked body 150 may include a first conductivity type semiconductor layer 152, an active layer 154, and a second conductivity type semiconductor layer 156.

In some embodiments, the first conductivity type semiconductor layer 152 may be and/or may include a nitride semiconductor having n-type composition (e.g., indium aluminum gallium nitride InₓAl_{y}Ga_{(1-x-y)}N, where 0≤x<1, 0≤y<1, and 0≤x+y<1), and in which, for example, the n-type impurity may be silicon (Si). As another example, the first conductivity type semiconductor layer 152 may include gallium nitride (GaN) including an n-type impurity.

In some embodiments, the first conductivity type semiconductor layer 152 may include a first conductivity type semiconductor contact layer and a current diffusion layer. An impurity concentration of the first conductivity type semiconductor contact layer may be in a range of about 2×10¹⁸ cm⁻³ to 9×10¹⁹ cm⁻³. However, the present disclosure is not limited thereof. A thickness of the first conductivity type semiconductor contact layer may be about 1 μm to about 5 μm. However, the present disclosure is not limited thereof. The current diffusion layer may have different compositions, or a structure in which a plurality of indium aluminum gallium nitride (InₓAl_{y}Ga_{(1-x-y)}N) layers with different impurity contents are alternately stacked. For example, the current diffusion layer may have an n-type superlattice structure in which n-type gallium nitride (GaN) layers and/or aluminum indium gallium nitride (AlₓIn_{y}Ga_{z}N, where 0≤x, y, z≤1 and x+y+z≠0) layers, each having a thickness of about 1 nm to about 500 nm, are alternately stacked. An impurity concentration of the current diffusion layer may be about 2×10¹⁸ cm⁻³ to about 9×10¹⁹ cm⁻³. However, the present disclosure is not limited thereof.

The active layer 154 may be disposed between the first conductivity type semiconductor layer 152 and the second conductivity type semiconductor layer 156. The active layer 154 may emit light with preset energy by recombination of electrons and holes when the semiconductor light-emitting device 100 is driven. The active layer 154 may have a multiple quantum well (MQW) structure in which quantum well layers and quantum barrier layers are alternately stacked. For example, the quantum well layer and the quantum barrier layer may each include indium aluminum gallium nitride (InₓAl_{y}Ga_{(1-x-y)}N) having different compositions. As another example, the quantum well layer may include indium gallium nitride (InxGa₁₋ₓN, where 0≤x≤1) and the quantum barrier layer may include gallium nitride (GaN) or aluminum gallium nitride (AlGaN). Thicknesses of the quantum well layer and the quantum barrier layer may each range from about 1 nm to about 50 nm. In an embodiment, the active layer 154 may have a single quantum well structure without being limited to the multi-quantum well structure.

The second conductivity type semiconductor layer 156 may be a nitride semiconductor layer with a composition of p-type indium aluminum gallium nitride (InₓAl_{y}Ga_{(1-x-y)}N), and for example, the p-type impurity may be magnesium (Mg). However, the present disclosure is not limited thereof.

In some embodiments, the second conductivity type semiconductor layer 156 may include an electron-blocking layer, a low-concentration p-type gallium nitride (GaN) layer, and a high-concentration p-type gallium nitride (GaN) layer, which may be stacked in a vertical direction. For example, the electron-blocking layer may have a structure in which a plurality of indium aluminum gallium nitride (InₓAl_{y}Ga_{(1-x-y)}N) layers of different compositions, each of the layers having a thickness of about 5 nm to about 100 nm, may be alternately stacked, or may be a single layer including aluminum gallium nitride (Al_{y}Ga_{(1-y)}N, where 0<y≤1). An energy band gap of the electron-blocking layer may decrease as a distance from the active layer 154 increases. For example, an aluminum (Al) composition of the electron-blocking layer may decrease as the distance from the active layer 154 increases.

The transparent electrode layer 160 may be on the light-emitting stacked body 150. The transparent electrode layer 160 may be over an upper surface of the first conductivity type semiconductor layer 152. In some embodiments, the transparent electrode layer 160 may also be on an upper surface of the second conductivity type semiconductor layer 156. For example, the transparent electrode layer 160 may be either a transparent conductive oxide layer or a nitride layer and may include, but not be limited to, at least one of indium tin oxide (InSnO), zinc-doped indium tin oxide (ZnInSnO), zinc indium oxide (ZnInO), gallium indium oxide (GaInO), zinc tin oxide (ZnSnO), fluorine-doped tin oxide (F-doped SnO), aluminum-doped zinc oxide (Al-doped ZnO), gallium-doped zinc oxide (Ga-doped ZnO), tin-doped indium oxide (In₄Sn₃O₁₂), or zinc magnesium oxide (Zn₍₁₋ₓ₎MgₓO, where 0≤x≤1). In some embodiments, the transparent electrode layer 160 may also include graphene (C).

The first electrode 172 may be on an upper surface of the first conductivity type semiconductor layer 152, and the second electrode 174 may be on an upper surface of the second conductivity type semiconductor layer 156. The first electrode 172 may include, but not be limited to, at least one of silver (Ag), nickel (Ni), aluminum (Al), chromium (Cr), rhodium (Rh), palladium (Pd), iridium (Ir), ruthenium (Ru), magnesium (Mg), zinc (Zn), platinum (Pt), and gold (Au). The second electrode 174 may have a reflective electrode structure. The second electrode 174 may include, but not be limited to, at least one of silver (Ag), nickel (Ni), aluminum (Al), chromium (Cr), rhodium (Rh), palladium (Pd), iridium (Ir), ruthenium (Ru), magnesium (Mg), zinc (Zn), platinum (Pt), and gold (Au). In some embodiments, the second electrode 174 may have a double-layer structure, such as nickel/silver (Ni/Ag), zinc/silver (Zn/Ag), nickel/aluminum (Ni/Al), zinc/aluminum (Zn/Al), palladium/silver (Pd/Ag), palladium/aluminum (Pd/Al), iridium/silver (Ir/Ag), iridium/gold (Ir/Au), platinum/aluminum (Pt/Al), or platinum/silver (Pt/Ag).

According to some embodiments, the protrusions 120 may be on an upper surface of the substrate 110, and the feature pattern P2 of the protrusions 120 may be formed of a material with a lower refractive index than the substrate 110. Accordingly, a light extraction efficiency of the semiconductor light-emitting device 100 may be increased, when compared to related semiconductor light-emitting devices.

In addition, as the intermediate layer 140 is between the buffer layer 130 and the light-emitting stacked body 150, abnormal crystal growth on an inclined surface of the protrusion 120 (e.g., on an inclined side surface of the buffer layer 130 arranged on the inclined surface of the protrusion 120) may be potentially reduced and/or prevented. Consequently, the light-emitting stacked body 150 may have an improved crystal quality, and thus, the semiconductor light-emitting device 100 may have improved optical characteristics, when compared to related semiconductor light-emitting devices.

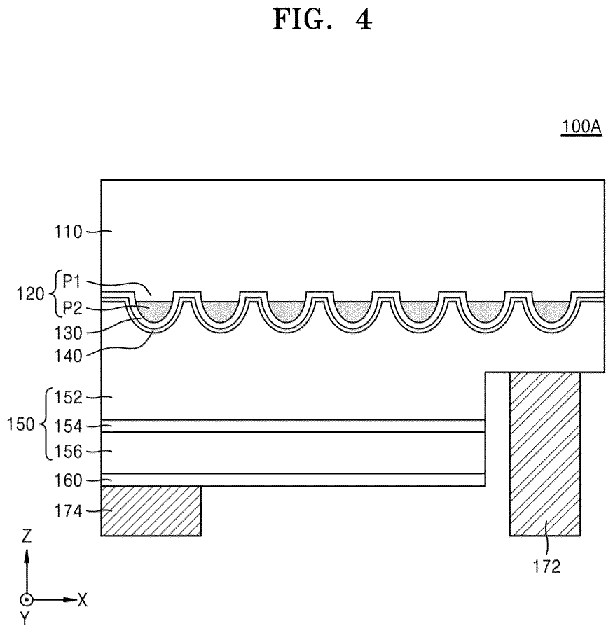

FIG. 4 is a cross-sectional view illustrating a semiconductor light-emitting device 100A, according to an embodiment.

The semiconductor light-emitting device 100A may include and/or may be similar in many respects to the semiconductor light-emitting device 100 described above with reference to FIGS. 1 to 3, and may include additional features not mentioned above. Consequently, repeated descriptions of the semiconductor light-emitting device 100A described above with reference to FIGS. 1 to 3 may be omitted for the sake of brevity.

Referring to FIG. 4, a substrate 110 may provide a light extraction surface, and the semiconductor light-emitting device 100A may be provided in a flip chip form. As used herein, one surface of the substrate 110 on which protrusions 120 are not formed may be referred to as an upper surface of the substrate 110, and one surface of the substrate 110 on which the protrusions 120 are formed may be referred to as a bottom surface of the substrate 110. The protrusions 120 may be arranged on the bottom surface of the substrate 110, and a buffer layer 130 and an intermediate layer 140 covering the protrusions 120 may be over the bottom surface of the substrate 110. A light-emitting stacked body 150 may be on the bottom surface of the substrate 110, and the protrusions 120, the buffer layer 130, and the intermediate layer 140 may be between the substrate 110 and the light-emitting stacked body 150. A first electrode 172 and a second electrode 174 may be respectively connected to a first conductivity type semiconductor layer 152 and a second conductivity type semiconductor layer 156 of the light-emitting stacked body 150. The first electrode 172 and the second electrode 174 may be attached onto a package substrate such that the upper surface of the substrate 110 or the light extraction surface of the substrate 110 faces upward, and accordingly, the semiconductor light-emitting device 100A of a flip-chip type may be provided.

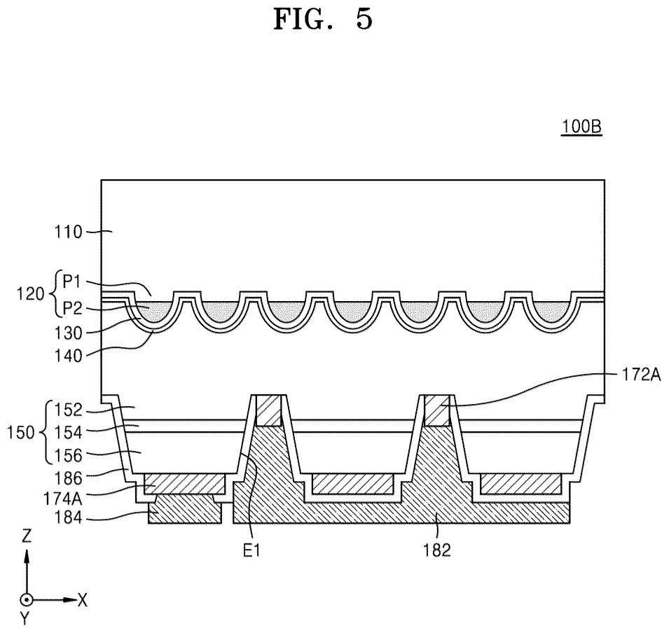

FIG. 5 is a cross-sectional view illustrating a semiconductor light-emitting device 100B, according to an embodiment.

The semiconductor light-emitting device 100B may include and/or may be similar in many respects to the semiconductor light-emitting devices 100 and 100A described above with reference to FIGS. 1 to 4, and may include additional features not mentioned above. Consequently, repeated descriptions of the semiconductor light-emitting device 100B described above with reference to FIGS. 1 to 4 may be omitted for the sake of brevity.

Referring to FIG. 5, the semiconductor light-emitting device 100B may include a substrate 110, protrusions 120, a buffer layer 130, an intermediate layer 140, and a light-emitting stacked body 150.

The substrate 110 may have a light extraction surface, and the semiconductor light-emitting device 100B may be provided in a flip chip form. As used herein, one surface of the substrate 110 on which the protrusions 120 are not formed may be referred to as an upper surface of the substrate 110, and one surface of the substrate 110 on which the protrusions 120 are formed may be referred to as a bottom surface of the substrate 110. The protrusions 120 may be arranged on the bottom surface of the substrate 110, and the buffer layer 130 and the intermediate layer 140 covering the protrusions 120 may be arranged on the bottom surface of the substrate 110. The light-emitting stacked body 150 may be over the bottom surface of the substrate 110, and the protrusions 120, the buffer layer 130, and the intermediate layer 140 may be between the substrate 110 and the light-emitting stacked body 150.

The light-emitting stacked body 150 may include a plurality of openings E1. The plurality of openings E1 may penetrate the second conductivity type semiconductor layer 156 and the active layer 154 to expose a surface of the first conductivity type semiconductor layer 152. An insulating liner 186 may be on an inner wall of each of the plurality of openings E1. A first electrode 172A in each of the plurality of openings E1 may be on a surface of the first conductivity type semiconductor layer 152, and a first pad electrode 182 fills the inside of the plurality of openings E1 and be electrically connected to the first electrode 172A. A second electrode 174A may be on a bottom surface of the second conductivity type semiconductor layer 156, and a second pad electrode 184 may be on the second electrode 174A. The first pad electrode 182 and the second pad electrode 184 may be attached onto a package substrate such that an upper surface of the substrate 110 or a light extraction surface of the substrate 110 faces upward, and accordingly, the semiconductor light-emitting device 100B of a flip-chip type may be provided.

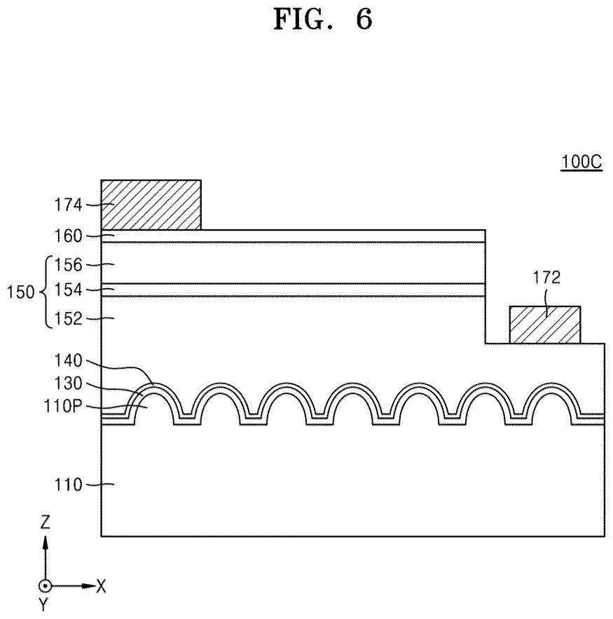

FIG. 6 is a cross-sectional view illustrating a semiconductor light-emitting device 100C, according to an embodiment.

The semiconductor light-emitting device 100C may include and/or may be similar in many respects to the semiconductor light-emitting devices 100, 100A, and 100B described above with reference to FIGS. 1 to 5, and may include additional features not mentioned above. Consequently, repeated descriptions of the semiconductor light-emitting device 100C described above with reference to FIGS. 1 to 5 may be omitted for the sake of brevity.

Referring to FIG. 6, a protrusion 110P may be defined on the substrate 110, and the protrusion 110P may be integrally connected to the substrate 110. The protrusion 110P may be formed by etching a part of the substrate 110, and for example, the protrusion 110P may include, but not be limited to, at least one of sapphire (Al₂O₃), silicon carbide (SiC), silicon (Si), magnesium aluminate (MgAl₂O₄), magnesium oxide (MgO), lithium aluminate (LiAlO₂), lithium gallium oxide (LiGaO₂), or gallium nitride (GaN). A buffer layer 130 and an intermediate layer 140 may be arranged on a surface of the protrusion 110P.

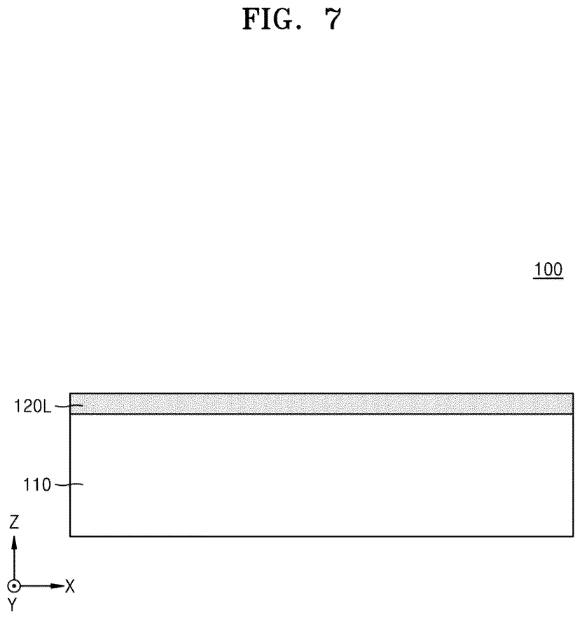

FIGS. 7 to 15 are cross-sectional views illustrating a method of manufacturing the semiconductor light-emitting device 100, according to an embodiment.

Referring to FIG. 7, a feature layer 120L may be formed on a substrate 110. The substrate 110 may include, but not be limited to, at least one of sapphire (Al₂O₃), silicon carbide (SiC), silicon (Si), magnesium aluminate (MgAl₂O₄), magnesium oxide (MgO), lithium aluminate (LiAlO₂), lithium gallium oxide (LiGaO₂), and gallium nitride (GaN). In some embodiments, the feature layer 120L may be formed of a material with a refractive index different from a refractive index of the substrate 110. In some embodiments, the feature layer 120L may have a refractive index of about 1.0 to about 1.7. For example, the feature layer 120L may include at least one of silicon oxide (SiOₓ), silicon oxynitride (SiOₓN_{y}), and magnesium fluoride (MgF₂). In some embodiments, the feature layer 120L may be formed by a chemical vapor deposition process, a physical vapor deposition process, an atomic layer deposition process, or so on.

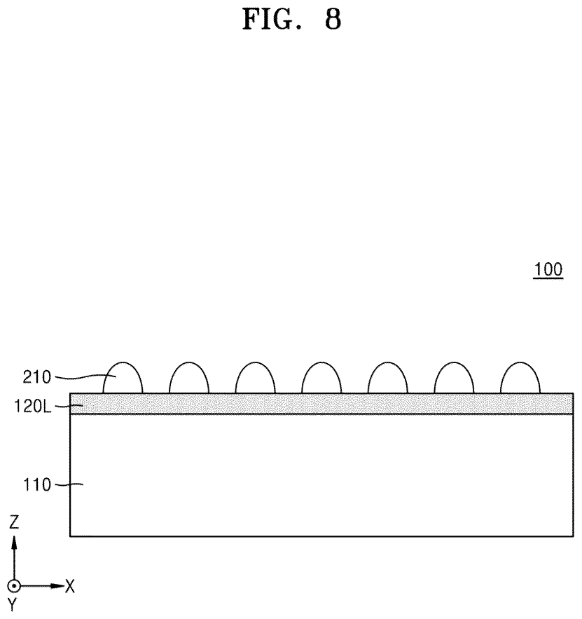

Referring to FIG. 8, a photoresist pattern 210 may be formed on the feature layer 120L.

In some embodiments, the photoresist pattern 210 may be formed by coating the feature layer 120L with a photoresist film and then performing an exposure and development process on the photoresist film. In some embodiments, the photoresist pattern 210 may be formed by performing a reflow process at a preset temperature. In such embodiments, the photoresist pattern 210 may have a shape that protrudes convexly upward or may have a hemispherical shape.

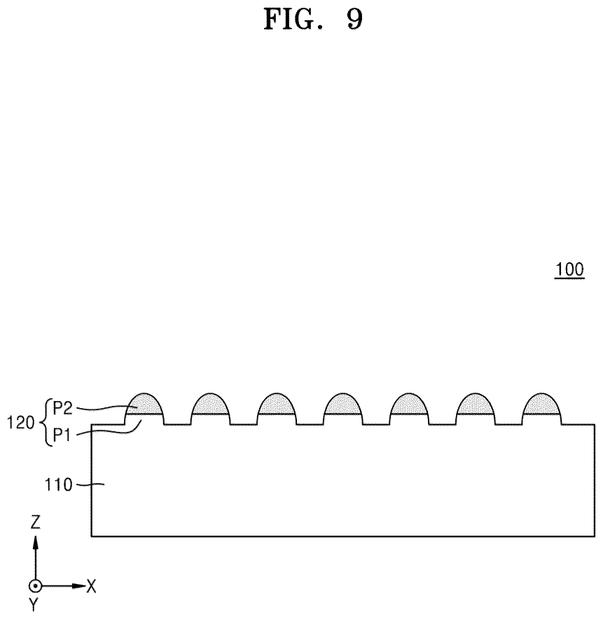

Referring to FIG. 9, a feature pattern P2 may be formed from the feature layer 120L by etching the feature layer 120L, for example, by a dry etching process, using the photoresist pattern 210 as an etching mask. In some embodiments, the shape of the photoresist pattern 210 may be transferred to the feature pattern P2 in an etching process, and accordingly, the feature pattern P2 may be formed to have a shape corresponding to a convex protruding shape of the photoresist pattern 210. In some embodiments, the feature pattern P2 may have a hemispherical shape or a cone shape.

In some embodiments, a dry etching process of forming the feature pattern P2 may be performed by using an etching gas, such as carbon tetrafluoride (CF₄), sulfur hexafluoride (SF₆), chlorine (Cl₂), boron trichloride (BCl₃), argon (Ar), or nitrogen (N).

A part of the substrate 110 may be further removed in an etching process of forming the feature pattern P2 or in another etching process after the etching process of forming the feature pattern P2, and accordingly, a lower pattern P1 may be formed beneath the feature pattern P2. The lower pattern P1 may be covered by the feature pattern P2 and may indicate a part of the substrate 110 which remains without being removed in the etching process. Subsequent to the etching process, an upper surface of the substrate 110 may be retracted or recessed and arranged at a vertical level lower than an upper surface of the lower pattern P1.

In an embodiment, the lower pattern P1 and the feature pattern P2 on the lower pattern P1 may be referred to as the protrusion 120. For example, the protrusion 120 may be in a hexagonal arrangement as shown in FIG. 3.

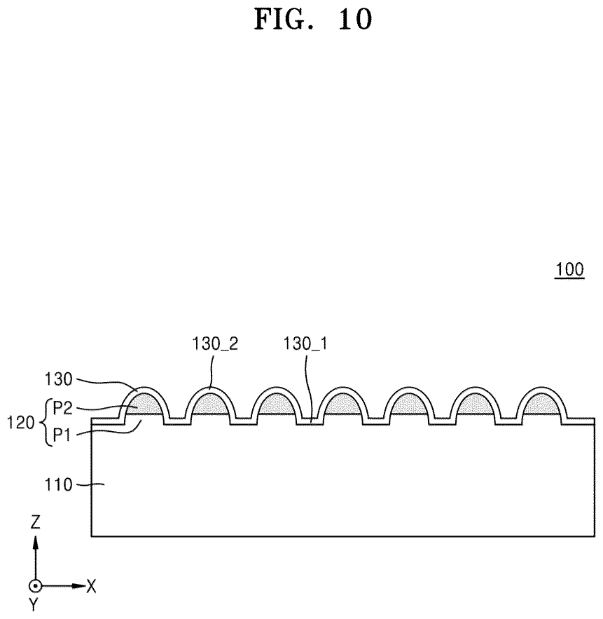

Referring to FIG. 10, a buffer layer 130 may be formed above the substrate 110 and the protrusion 120.

In some embodiments, the buffer layer 130 may include, but not be limited to, at least one of aluminum nitride (AlN), gallium nitride (GaN), indium nitride (InN), indium gallium nitride (InGaN), aluminum gallium nitride (AlGaN), indium aluminum gallium nitride (InAlGaN), or aluminum indium nitride (AlInN). In some embodiments, the buffer layer 130 may be formed by a physical vapor deposition process, a chemical vapor deposition process, or an atomic layer deposition process at a temperature of about 500° C. to about 600° C.

The buffer layer 130 may include a first portion 130_1 that has a flat upper surface and is arranged on an upper surface of the substrate 110, and a second portion 130_2 that convexly protrudes and covers an upper surface of the protrusion 120. For example, the second portion 130_2 of the buffer layer 130 may be in contact with an upper surface of the feature pattern P2 and a sidewall of the lower pattern P1.

In some embodiments, the buffer layer 130 may have a first thickness t1 and, for example, the first thickness t1 may range from about 5 nm to about 30 nm. However, the present disclosure is not limited thereof.

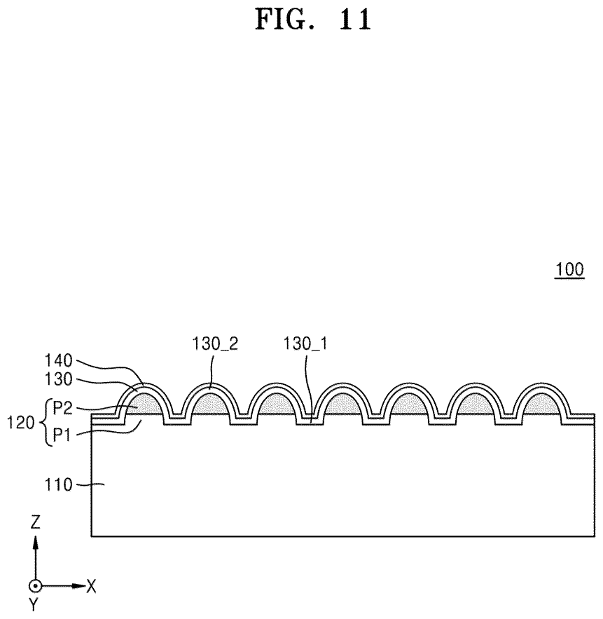

Referring to FIG. 11, an intermediate layer 140 may be formed on the buffer layer 130.

In some embodiments, the intermediate layer 140 may be formed of silicon nitride (SiN). For example, the intermediate layer 140 may have a second thickness t2, and the second thickness t2 may range from about 1 Å to about 1 nm. However, the present disclosure is not limited thereof. The intermediate layer 140 may be conformally arranged on the first portion 130_1 and the second portion 130_2 of the buffer layer 130.

In some embodiments, the intermediate layer 140 may be formed by forming a monolayer on a surface of the buffer layer 130 or forming five (5) or less material layers through an ALD process. In some embodiments, the intermediate layer 140 may be formed by forming ten (10) or less material layers on a surface of the buffer layer 130 through an ALD process. In some embodiments, a monolayer of silicon nitride (SiN) may be formed by continuously supplying a silicon (Si) precursor, purging the silicon (Si) precursor, supplying a reactant including nitrogen (N), and purging the reactant in the ALD process. In some embodiments, the intermediate layer 140 may be formed by repeating several to dozens of times a unit deposition cycle consisting of supplying a silicon (Si) precursor, purging the silicon (Si) precursor, supplying a reactant including nitrogen (N), and purging the reactant.

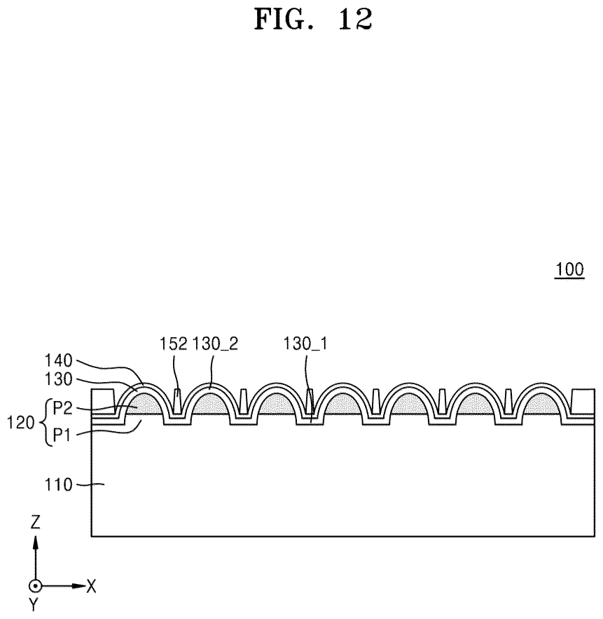

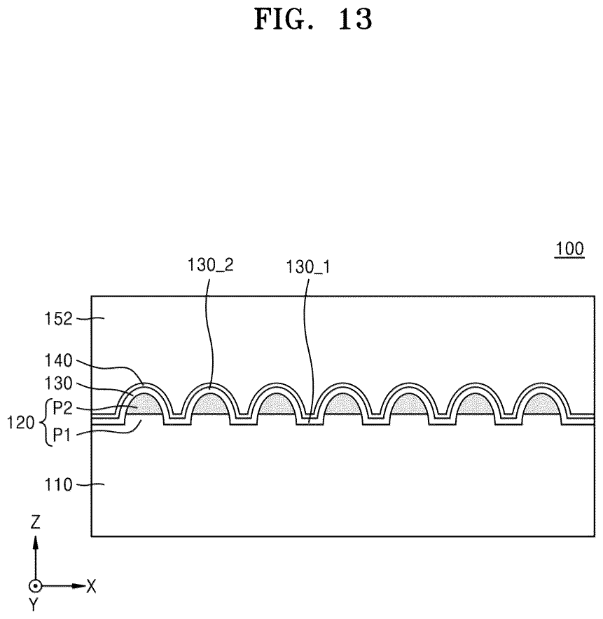

Referring to FIGS. 12 and 13, a first conductivity type semiconductor layer 152 may be grown on an upper surface of the intermediate layer 140. As shown in FIG. 12, the first conductivity type semiconductor layer 152 may be nucleated and epitaxially grown on the first portion 130_1 of the buffer layer 130 and the intermediate layer 140 arranged thereon. The first conductivity type semiconductor layer 152 may not be nucleated on a second portion 130_2 of the buffer layer 130 and the intermediate layer 140 arranged thereon.

In a related method of manufacturing a related semiconductor light-emitting device in which the intermediate layer 140 may not be formed, a pseudo-crystal surface on which a single crystal growth may be done may be on an inclined surface (e.g., the second portion 130_2) of the buffer layer 130, and accordingly, nucleation may occur on the inclined surface of the buffer layer 130. Consequently, a crystal quality of the first conductivity type semiconductor layer 152 may be reduced due to crystal grains nucleated on the inclined surface of the buffer layer 130.

In some embodiments, as the intermediate layer 140 is on the inclined surface of the buffer layer 130 (e.g., on the second portion 130_2 of the buffer layer 130), the first conductivity type semiconductor layer 152 may not be nucleated on the inclined surface, and as the first conductivity type semiconductor layer 152 is nucleated solely on a flat upper surface of the buffer layer 130, that is, on the first portion 130_1 of the buffer layer 130 (on the intermediate layer 140 on the buffer layer 130), the crystal quality of the first conductivity type semiconductor layer 152 may potentially be increased, when compared to the related semiconductor light-emitting device.

As shown in FIG. 13, the first conductivity type semiconductor layer 152 may be grown laterally through an epitaxial lateral overgrowth process. Accordingly, the first conductivity type semiconductor layer 152 may be formed to have a sufficiently large thickness to completely cover the protrusions 120 and may have a flat top surface.

As the first conductivity type semiconductor layer 152 epitaxially and laterally overgrows from an upper surface of the first portion 130_1 of the buffer layer 130, dislocation defects occurring due to the difference in lattice constant between the substrate 110 and the first conductivity type semiconductor layer 152 may not propagate upward. Accordingly, a dislocation density within the first conductivity type semiconductor layer 152 may be reduced, and the crystal quality may potentially be increased, when compared to the related semiconductor light-emitting device.

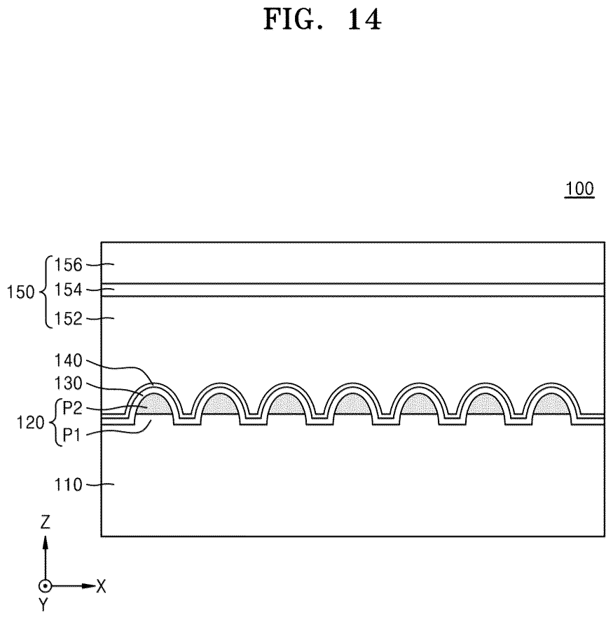

Referring to FIG. 14, a light-emitting stacked body 150 may be formed by sequentially forming an active layer 154 and a second conductivity type semiconductor layer 156 on the first conductivity type semiconductor layer 152.

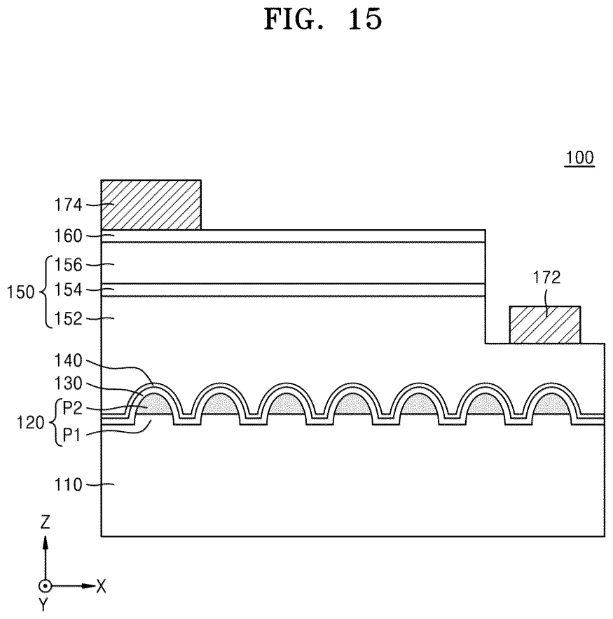

Referring to FIG. 15, a part of the light-emitting stacked body 150 may be etched to expose an upper surface of the first conductivity type semiconductor layer 152. Thereafter, a first electrode 172 may be formed on an upper surface of the first conductivity type semiconductor layer 152, and a transparent electrode layer 160 and a second electrode 174 may be formed on an upper surface of the second conductivity type semiconductor layer 156.

The semiconductor light-emitting device 100 may be manufactured by performing the above-described processes with reference to FIGS. 7 to 15.

According to the method of manufacturing the semiconductor light-emitting device, according to the embodiment, the intermediate layer 140 may prevent abnormal crystal growth on an inclined surface of the protrusion 120 during an epitaxial growth process of the light-emitting stacked body 150. Accordingly, crystallinity of the light-emitting stacked body 150 may potentially be improved, and the semiconductor light-emitting device 100 may have a potentially improved light extraction efficiency, when compared to related semiconductor light-emitting devices.

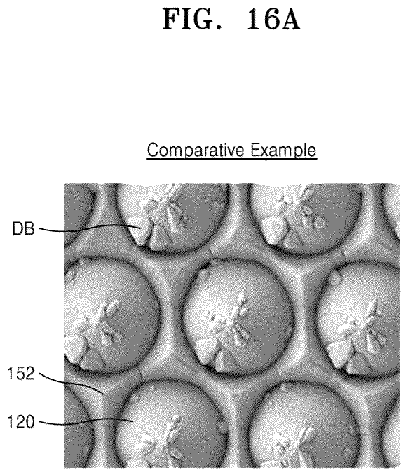

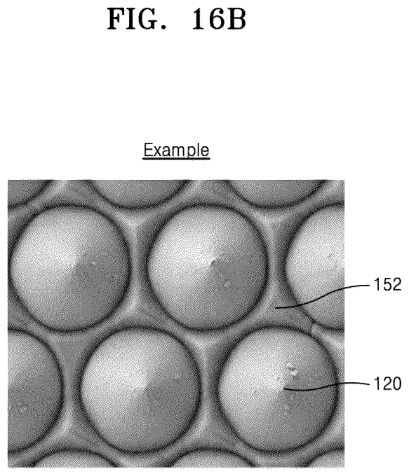

FIGS. 16A and 16B are SEM images illustrating protrusions and a first-conductivity-type semiconductor layer in a crystal growth process, according to a comparative example and an example, respectively.

In a related method of manufacturing a semiconductor light-emitting device according to the comparative example, the buffer layer 130 may be formed on the protrusion 120, an intermediate layer may not be formed on the buffer layer 130, and an epitaxial growth process of forming the first conductivity type semiconductor layer 152 on the buffer layer 130 may be performed. FIG. 16A illustrates a planar shape of the first conductivity type semiconductor layer 152 and the protrusions 120 at the time when the first conductivity type semiconductor layer 152 grows to have a preset thickness in a state where the buffer layer 130 is formed on the protrusions 120.

Referring to FIG. 16A, in the related method of manufacturing a semiconductor light-emitting device according to the comparative example, it may be observed that crystallite debris DB, such as nucleation seeds or nucleation crystals, is formed on an inclined surface of the protrusion 120 (e.g., on the second portion 130_2 of the buffer layer 130). The crystallite debris DB may be formed due to the inclined surface of the protrusion 120 acting as a pseudo-crystal surface for crystal growth and causing abnormal crystal growth on the inclined surface of the protrusion 120. The crystallite debris DB may cause dislocations to occur in the first conductivity type semiconductor layer 152, and accordingly, the crystal quality of the first conductivity type semiconductor layer 152 may be reduced.

Aspects of the present disclosure provide a method of manufacturing a semiconductor light-emitting device 100, according to an example, in which the buffer layer 130 may be formed on the protrusions 120, the intermediate layer 140 may be formed on the buffer layer 130, and an epitaxial growth process of forming the first conductivity type semiconductor layer 152 on the intermediate layer 140 may be performed. FIG. 16B illustrates a planar shape of the first conductivity type semiconductor layer 152 and the protrusions 120 at the time when the first conductivity type semiconductor layer 152 grows to have a preset thickness in a state where the buffer layer 130 and the intermediate layer 140 are formed on the protrusions 120.

Referring to FIG. 16B, the crystallite debris DB, such as nucleation seeds or nucleation crystals, may not be formed on an inclined surface of the protrusion 120 (e.g., on the second portion 130_2 of the buffer layer 130), and instead, it may be observed that the inclined surface of the protrusion 120 (e.g., an upper surface of the intermediate layer 140 arranged on the second portion 130_2 of the buffer layer 130) is maintained as smooth and clean surfaces. Accordingly, the first conductivity type semiconductor layer 152 may prevent and/or reduce crystal defects, such as dislocations, from occurring in the first conductivity type semiconductor layer 152, and accordingly, the crystal quality of the first conductivity type semiconductor layer 152 may be increased, when compared to the related semiconductor light-emitting devices.

Table 1 below shows an X-ray diffraction analysis graph results of the first conductivity type semiconductor layer 152 obtained by the method of manufacturing a semiconductor light emitting device, according to a comparative example, and the method of manufacturing a semiconductor light emitting device, according to an example. In particular, a full width at half maximum of a (002) peak in an X-ray diffraction analysis graph of the first conductivity type semiconductor layer 152 is compared. The full width at half maximum may indicate a peak width at a point with an intensity of half the maximum intensity at the (002) peak. As shown in Table 1, the full width at half maximum of the (002) peak according to the comparative example is 150 arcseconds, and in contrast to this, the full width at half maximum of the (002) peak according to the example is 144 arcseconds, and as such, crystallinity is improved when compared to the comparative example.

In the manufacturing method according to an embodiment, even when the intermediate layer 140 is formed of silicon nitride (SiN) on the buffer layer 130 to have a preset thickness, the intermediate layer 140 may be formed to be relatively thin and may not interfere with crystal growth of the first conductivity type semiconductor layer 152, and in particular, may prevent and/or reduce a defect-causing factor, such as abnormal growth on an inclined surface, from occurring, and thus, the first conductivity type semiconductor layer 152 may have an improved crystal quality, when compared to related semiconductor light-emitting devices.

TABLE 1
X-Ray Diffraction Analysis
Full Width at Half Maximum of (002) Peak of X-Ray Diffraction
Analysis Graph of First Conductivity Type Semiconductor Layer

| | |
|---|---|
| Comparative Example | 150 arcsec |
| Example | 144 arcsec |

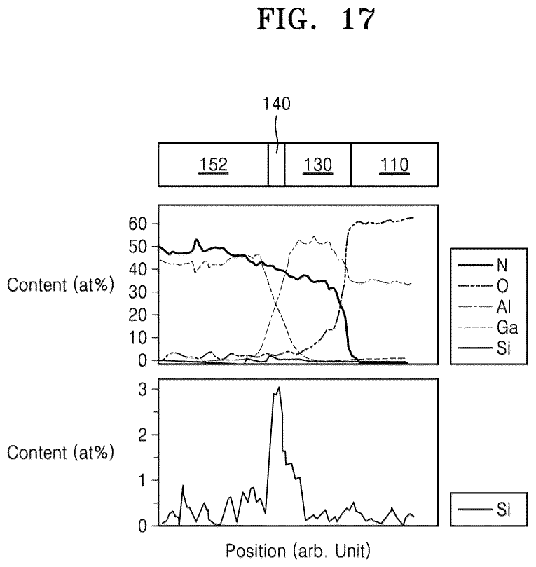

FIG. 17 is a graph illustrating TEM-EDS observation results of a semiconductor light-emitting device, according to an embodiment.

Referring to FIG. 17, a relatively thin intermediate layer 140 may be between the first conductivity type semiconductor layer 152 and the buffer layer 130, and as a result of elemental composition analysis by TEM-EDS measurement, it may be seen that a silicon (Si) element is observed to have a relatively large content at a position corresponding to the intermediate layer 140.

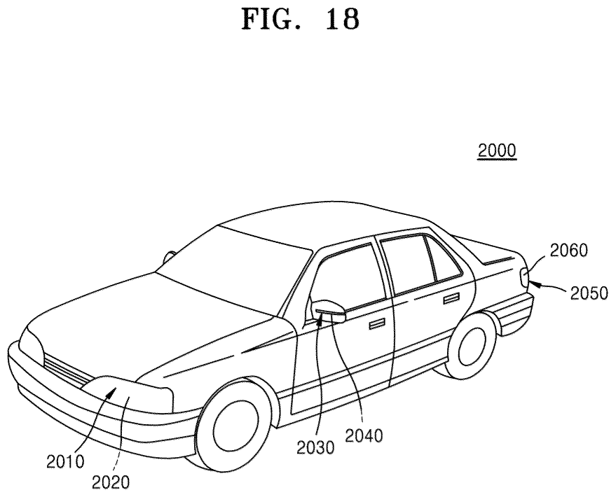

FIG. 18 is a perspective view schematically illustrating a lighting device including a semiconductor light-emitting device, according to an embodiment.

Referring to FIG. 18, a head lamp module 2020 may be installed in a head lamp unit 2010 of a vehicle, a side mirror lamp module 2040 may be installed in an external side mirror unit 2030, and a tail lamp module 2060 may be installed in a tail lamp unit 2050. At least one of the head lamp module 2020, the side mirror lamp module 2040, and the tail lamp module 2060 may be a light source module including at least one of the semiconductor light-emitting devices 100, 100A, 100B, and 100C described above with reference to FIGS. 1 to 15.

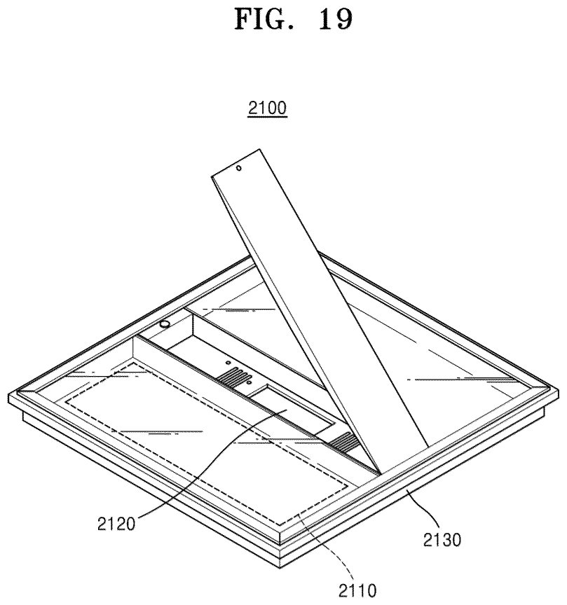

FIG. 19 is a schematic perspective view of a plate lighting device including a semiconductor light-emitting device, according to an embodiment.

Referring to FIG. 19, a plate lighting device 2100 may include a light source module 2110, a power supply 2120, and a housing 2130.

The light source module 2110 may include a light emitting device array as a light source and may include at least one of the semiconductor light-emitting devices 100, 100A, 100B, and 100C, described above with reference to FIGS. 1 to 15, as a light source. The light source module 2110 may have a planar shape as a whole.

The power supply 2120 may supply power to the light source module 2110. The housing 2130 may have an accommodation space to accommodate the light source module 2110 and the power supply device 2120 therein and may have one side formed in a hexahedral shape but is not limited thereto. The light source module 2110 may be arranged to emit light through one open side of the housing 2130.

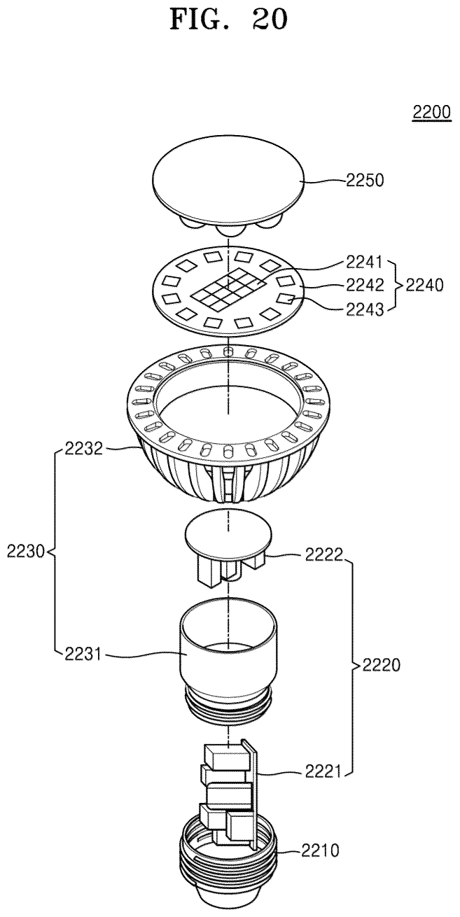

FIG. 20 is a schematic exploded perspective view of a lighting device including a semiconductor light-emitting device, according to an embodiment.

Referring to FIG. 20, a lighting device 2200 may include a socket 2210, a power supply unit 2220, a heat dissipation unit 2230, a light source module 2240, and an optical unit 2250.

The socket 2210 may replace the existing lighting device. The power supplied to the lighting device 2200 may be applied through the socket 2210. The power supply unit 2220 may include a first power unit 2221 and a second power unit 2222 to be assembled into one body. The heat dissipation unit 2230 may include an internal heat dissipation unit 2231 and an external heat dissipation unit 2232, the internal heat dissipation unit 2231 may be directly connected to the light source module 2240 and/or the power supply unit 2220, and therethrough, heat may be transferred to the external heat dissipation unit 2232. In an embodiment, the optical unit 2250 may include an internal optical unit and an external optical unit and may evenly distribute the light emitted by the light source module 2240.

The light source module 2240 may receive power from the power supply unit 2220 and emit light to the optical unit 2250. The light source module 2240 may include one or more light emitting device packages 2241, a circuit board 2242, and a controller 2243, and the controller 2243 may store drive information of the light emitting device packages 2241. The light emitting device packages 2241 may each include at least one of the semiconductor light-emitting devices 100, 100A, 100B, and 100C described above with reference to FIGS. 1 to 15.

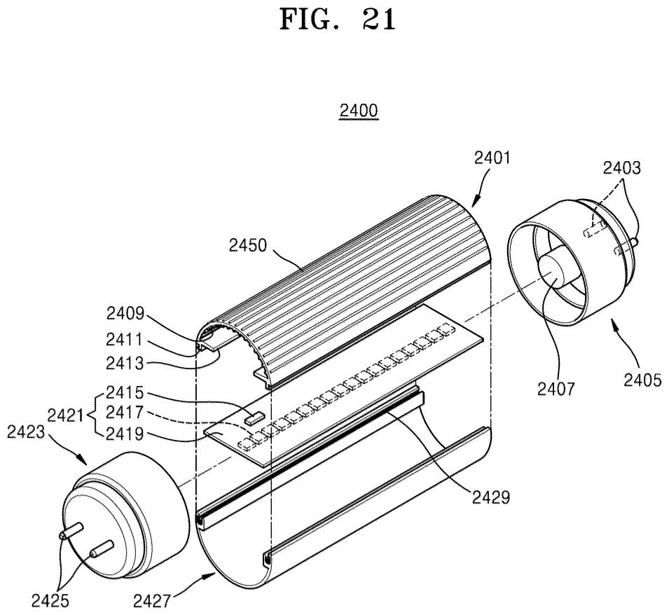

FIG. 21 is an exploded perspective view schematically illustrating a bar-type lighting device including a semiconductor light-emitting device, according to an embodiment.

Referring to FIG. 21, a lighting device 2400 may include a heat dissipation member 2401, a cover 2427, a light source module 2421, a first socket 2405, and a second socket 2423. A plurality of heat dissipation fins 2450 and 2409 may be formed in an uneven shape on an inner surface or/and outer surface of the heat dissipation member 2401, and the heat dissipation fins 2450 and 2409 may be designed to have various shapes and spacings. A support 2413 having a protruding shape may be formed inside the heat dissipation member 2401. The light source module 2421 may be fixed to the support 2413. Locking jaws 2411 may be formed at both ends of the heat dissipation member 2401.

A locking groove 2429 may be formed in the cover 2427, and the locking jaw 2411 of the heat dissipation member 2401 may be coupled to the locking groove 2429 in a hook coupling structure. Positions where the locking groove 2429 and the locking jaw 2411 are formed may be changed with one another.

The light source module 2421 may include a printed circuit board 2419, a light source 2417, and a controller 2415. The controller 2415 may store drive information of the light source 2417. Circuit wires for operating the light source 2417 may be formed in the printed circuit board 2419. In addition, components for operating the light source 2417 may also be included in the printed circuit board 2419. The light source 2417 may include at least one of the semiconductor light-emitting devices 100, 100A, 100B, and 100C described above with reference to FIGS. 1 to 15.

The first socket 2405 and the second socket 2423 are a pair of sockets and may be coupled to both ends of a cylindrical cover unit including the heat dissipation member 2401 and the cover 2427. For example, the first socket 2405 may include an electrode terminal 2403 and a power supply 2407, and a dummy terminal 2425 may be arranged in the second socket 2423. In addition, an optical sensor and/or a communication module may be built in either the first socket 2405 or the second socket 2423.

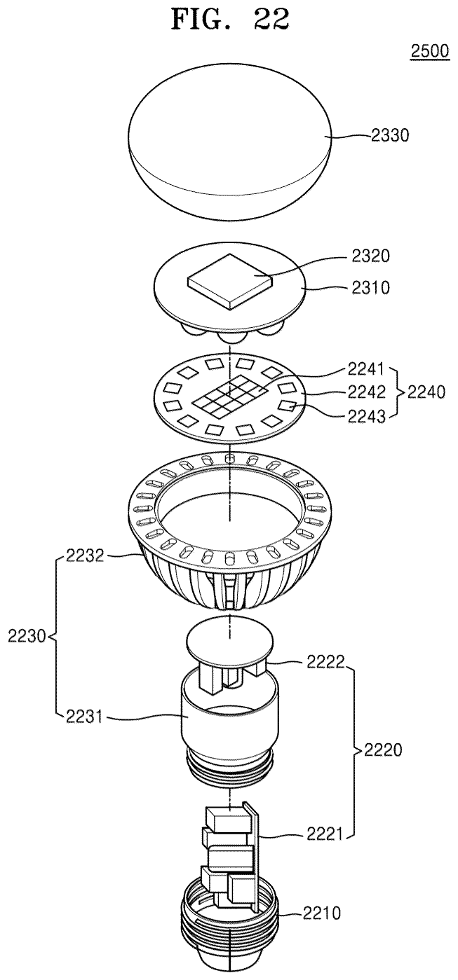

FIG. 22 is an exploded perspective view schematically illustrating a lighting device including a semiconductor light-emitting device, according to an embodiment.

Referring to FIG. 22, including a reflector 2310 and a communication module 2320 on an upper portion of the light source module 2240 is a difference between the lighting device 2500 according to the present embodiment and the lighting device 2200 illustrated in FIG. 20. The reflector 2310 may reduce glare by evenly spreading the light from a light source to the sides and rear.

The communication module 2320 may be mounted on an upper portion of the reflector 2310, and home-network communication may be implemented by the communication module 2320. For example, the communication module 2320 may include a wireless communication module using ZigBee, Wireless-Fidelity (WiFi), Light-Fidelity (LiFi), or the like, and may control lighting of a lighting device installed inside and outside a home, such as turn-on and turn-off and brightness adjustment thereof, through a smartphone or wireless controller, or may control electronic appliances installed inside and outside the home, such as a television (TV), a refrigerator, an air conditioner, and a door lock, cars, and automotive systems. The reflector 2310 and the communication module 2320 may be covered by a cover unit 2330.

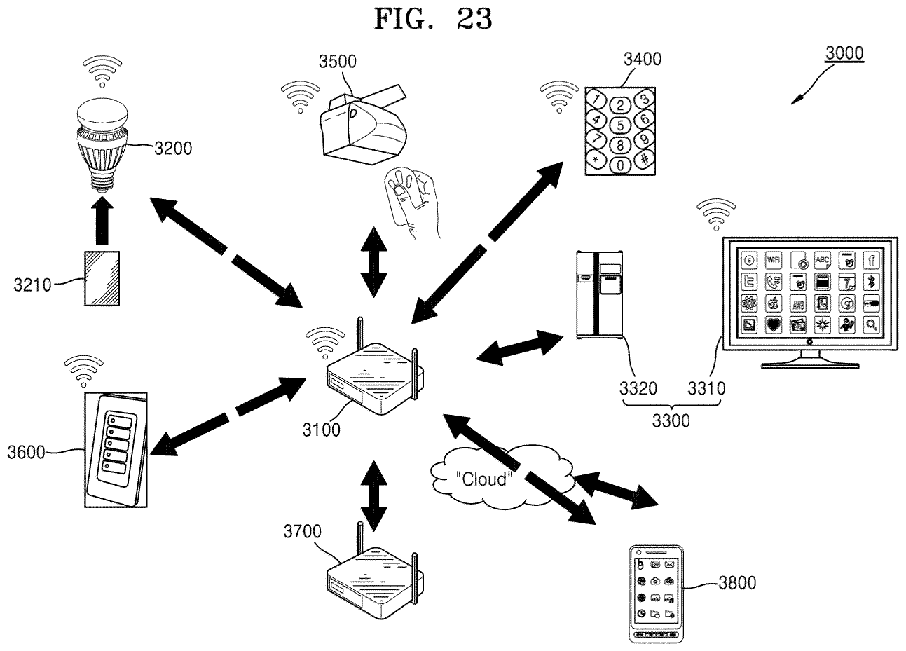

FIG. 23 is a schematic diagram illustrating an indoor lighting control network system including a semiconductor light-emitting device, according to an embodiment.

Referring to FIG. 23, a network system 3000 may include a complex smart lighting-network system in which lighting technology using a light-emitting device, such as a light-emitting diode (LED), Internet of Things (IoT) technology, and wireless communication technology are combined with each other. The network system 3000 may be implemented by various lighting devices and wired and wireless communication devices or may be implemented based on an IoT environment to collect and process various types of information and provide the various types of information to users.

An LED lamp 3200 included in the network system 3000 may receive information on a surrounding environment from a gateway 3100, control lighting of the LED lamp 3200 itself, and perform functions, such as checking and controlling operation states of a plurality of devices 3300 to 3800 included in the IoT environment based on a function, such as visible light communication of the LED lamp 3200. The LED lamp 3200 may include at least one of the semiconductor light-emitting devices 100, 100A, 100B, and 100C described above with reference to FIGS. 1 to 15. The LED lamp 3200 may be communicably connected to the gateway 3100 by a wireless communication protocol, such as, but not limited to, WiFi, Zigbee, or LiFi, and may have at least one lamp communication module 3210 for this purpose.

When the network system 3000 is applied to a home, the plurality of devices 3300 to 3800 may include home appliances 3300, a digital door lock 3400, a garage door lock 3500, a lighting switch 3600 installed on a wall or so on, a router 3700 for a wireless communication network relay, and mobile devices 3800, such as smartphones, tablets, and laptop computers.

In the network system 3000, the LED lamp 3200 may check operation states of the plurality of devices 3300 to 3800 through a wireless communication network (e.g., Zigbee, WiFi, LiFi, or the like) installed in a home or may automatically adjust the illuminance of the LED lamp 3200 itself depending on surrounding environments and situations. In addition, the plurality of devices 3300 to 3800 included in the network system 3000 may also be controlled through LiFi communication using the visible light emitted from the LED lamp 3200.

In an embodiment, the LED lamp 3200 may automatically adjust lighting of the LED lamp 3200 based on surrounding environment information transmitted from the gateway 3100 through the lamp communication module 3210 or surrounding environment information collected from a sensor mounted on the LED lamp 3200. For example, the lighting brightness of the LED lamp 3200 may be automatically adjusted depending on the type of program being broadcasted on a television 3310 or the brightness of a screen. To this end, the LED lamp 3200 may receive operation information of the television 3310 from the lamp communication module 3210 connected to the gateway 3100. The lamp communication module 3210 may be integrated with a sensor and/or controller included in the LED lamp 3200.

For example, electricity waste may be potentially reduced and/or prevented by turning off the LED lamp 3200, which may be turned on when a certain period of time elapses after the digital door lock 3400 is locked while no one is in a home. Alternatively or additionally, in a state where a security mode is set through the mobile device 3800 or the like, when the digital door lock 3400 is locked while there is no one in a home, the LED lamp 3200 may also be maintained in a turn-on state.

An operation of the LED lamp 3200 may also be controlled according to the surrounding environment information collected through various sensors connected to the network system 3000. For example, when the network system 3000 is installed in a building, lighting devices, position sensors, and communication modules, which may be installed in a building and combined with each other, may collect position information of people in the building and turn on and/or off the lighting devices and/or provide the collected information in real time, and thus, a facility may be efficiently managed and an idle space may be efficiently used.

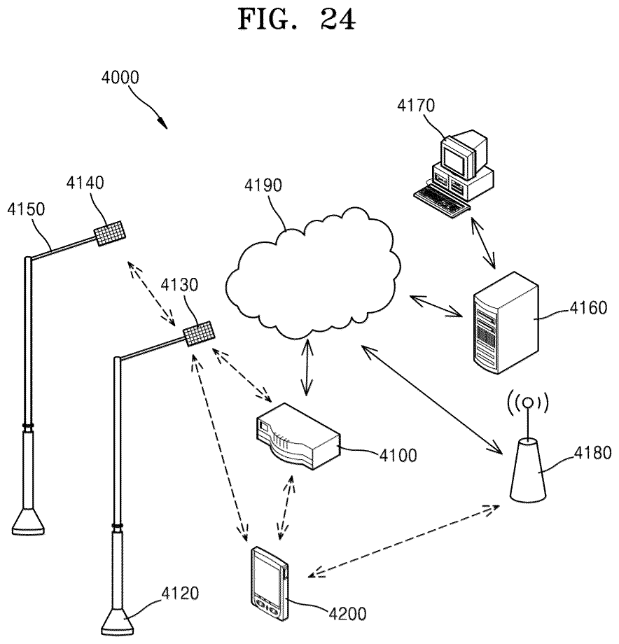

FIG. 24 is a schematic diagram illustrating a network system including a semiconductor light-emitting device, according to an embodiment.

FIG. 24 illustrates an embodiment of a network system 4000 applied to an open space. The network system 4000 may include a communication connection device 4100, a plurality of lighting fixtures (e.g., a first lighting fixture 4120 and a second lighting fixture 4150) installed at preset intervals and communicably connected to the communication connection device 4100, a server 4160, a computer 4170 for controlling the server 4160, a communication base station 4180, a communication network 4190 connecting communicable devices to each other, and a mobile device 4200.

The plurality of lighting fixtures 4120 and 4150 may be installed in an open external space, such as, but not limited to, a street or a park, and may respectively include smart engines (e.g., a first smart engine 4130 and a second smart engine 4140). The first and second smart engines 4130 and 4140 may include a light-emitting device for emitting light, a driver for driving the light-emitting device, a sensor for collecting information on a surrounding environment, a communication module, and so on. The light emitting device included in the first or second smart engine 4130 or 4140 may include at least one of the semiconductor light-emitting devices 100, 100A, 100B, and 100C described above with reference to FIGS. 1 to 15.

The first and second smart engines 4130 and 4140 may communicate with other surrounding devices according to communication protocols of a communication module, such as, but not limited to, WiFi, Zigbee, and LiFi. The first smart engine 4130 may be communicably connected to the second smart engine 4140, and a WiFi expansion technology (e.g., WiFi Mesh) may be used for communication between the first and second smart engines 4130 and 4140. The first smart engine 4130 may be connected to the communication connection device 4100 and/or connected to the communication network 4190 through wired/wireless communication.

The communication connection device 4100 may include an access point (AP) that may perform wired or wireless communication and may mediate communication between the communication network 4190 and other devices. The communication connection device 4100 may be connected to the communication network 4190 by at least one of wired and wireless communications, and, for example, may be mechanically stored inside the first or second lighting fixture 4120 or 4150.

The communication connection device 4100 may be connected to the mobile device 4200 through a communication protocol such as, but not limited to, WiFi. A user of the mobile device 4200 may receive the surrounding environment information, which may be collected by the plurality of smart engines 4130 and 4140 through the communication connection device 4100 connected to the smart engine 4130 of the adjacent surrounding lighting fixture 4120, which may include, but not be limited to, surrounding traffic information, weather information, or the like. The mobile device 4200 may also be connected to the communication network 4190 through the communication base station 4180 in a wireless cellular communication manner, such as, but not limited to, a third generation (3G) network, a fourth generation (4G) network, a fifth generation (5G) network, or the like.

In an embodiment, the server 4160 connected to the communication network 4190 may receive the information collected by the first and second smart engines 4130 and 4140 respectively mounted on the first and second lighting fixtures 4120 and 4150 and simultaneously monitor operation states and the like of the first and second lighting fixtures 4120 and 4150. The server 4160 may be connected to the computer 4170 that may provide a management system, and the computer 4170 may execute software and the like that may monitor and manage the operation states of the first and second smart engines 4130 and 4140.

A semiconductor light-emitting device, according to an embodiment, may include protrusions arranged on a substrate and may include a buffer layer and an intermediate layer covering the protrusions. The intermediate layer may prevent abnormal crystal growth on inclined surfaces of the protrusions during an epitaxial growth process of a light-emitting stacked body. Accordingly, the crystallinity of the light-emitting stacked body may be improved, and the semiconductor light-emitting device may also have improved light extraction efficiency, when compared to related semiconductor light-emitting devices.

As described above, embodiments are disclosed in the drawings and specification. Although embodiments are described in the present disclosure by using certain terms, this is used only for the purpose of describing the technical idea of the present disclosure and is not used to limit the meaning or scope of the present disclosure as set forth in the claims. Therefore, those skilled in the art are to understand that various modifications and other equivalent embodiments may be derived therefrom. Therefore, the true technical protection scope of the present disclosure should be determined by the technical idea of the attached claims.

While the present disclosure has been particularly illustrated and described with reference to embodiments thereof, it is to be understood that various changes in form and details may be made therein without departing from the spirit and scope of the following claims.

What is claimed is:

1. A semiconductor light-emitting device, comprising:
a substrate comprising a first material;
a plurality of protrusions, each protrusion of the plurality of protrusions comprising:
a lower pattern comprising a same material as the first material of the substrate; and
a feature pattern disposed on the lower pattern and comprising a second material different from the first material of the substrate;
a buffer layer on the substrate and the plurality of protrusions;
an intermediate layer on the buffer layer; and
a light-emitting stacked body on the intermediate layer,
wherein the intermediate layer comprises silicon nitride (SiN).

2. The semiconductor light-emitting device of claim 1, wherein the intermediate layer is conformally disposed on an upper surface of the substrate and on side surfaces and upper surfaces of the plurality of protrusions.

3. The semiconductor light-emitting device of claim 1, wherein the intermediate layer has a thickness of 1 angstrom (Å) to 1 nanometer (nm).

4. The semiconductor light-emitting device of claim 1, wherein the buffer layer comprises at least one of aluminum nitride (AlN), gallium nitride (GaN), indium nitride (InN), indium gallium nitride (InGaN), aluminum gallium nitride (AlGaN), indium aluminum gallium nitride (InAlGaN), or aluminum indium nitride (AlInN), and
wherein the buffer layer has a thickness of 5 nanometers (nm) to 30 nm.

5. The semiconductor light-emitting device of claim 1, wherein the feature pattern comprises the second material with a lower refractive index than a refractive index of the first material of the substrate.

6. The semiconductor light-emitting device of claim 1, wherein a refractive index of the feature pattern ranges from 1.0 to 1.7.

7. The semiconductor light-emitting device of claim 1, wherein the feature pattern comprises at least one of silicon oxide (SiOₓ), silicon oxynitride (SiOₓN_{y}), or magnesium fluoride (MgF₂).

8. The semiconductor light-emitting device of claim 1, wherein the feature pattern has at least one of a hemispherical shape or a cone shape.

9. The semiconductor light-emitting device of claim 1, wherein a first height of the lower pattern is less than or equal to a second height of the feature pattern.

10. The semiconductor light-emitting device of claim 9, wherein the first height of the lower pattern is measured from an upper surface of the substrate at least partially surrounding each of the plurality of protrusions to an upper surface of the lower pattern,
wherein the second height of the feature pattern is measured from the upper surface of the lower pattern to an uppermost portion of the feature pattern,
wherein the first height of the lower pattern ranges from 200 nanometers (nm) to 400 nm, and
wherein the second height of the feature pattern ranges from 200 nm to 2 micrometers.

11. The semiconductor light-emitting device of claim 10, wherein a ratio of the second height of the feature pattern to a height of each of the plurality of protrusions ranges from 0.5 to 0.9.

12. The semiconductor light-emitting device of claim 1, wherein the first material of the substrate comprises at least one of sapphire (Al₂O₃), silicon carbide (SiC), silicon (Si), magnesium aluminate (MgAl₂O₄), magnesium oxide (MgO), lithium aluminate (LiAlO₂), lithium gallium oxide (LiGaO₂), and gallium nitride (GaN).

13. The semiconductor light-emitting device of claim 1, wherein the light-emitting stacked body comprises a first conductivity type semiconductor layer, an active layer, and a second conductivity type semiconductor layer, which are sequentially disposed on the intermediate layer.

14. A semiconductor light-emitting device, comprising:
a substrate comprising a first material;
a plurality of protrusions, each protrusion of the plurality of protrusions comprising:
a lower pattern comprising a same material as the first material of the substrate; and
a feature pattern disposed on the lower pattern and comprising a second material different from the first material of the substrate;
a buffer layer on the substrate and the plurality of protrusions;
an intermediate layer on the buffer layer; and
a light-emitting stacked body comprising a first conductivity type semiconductor layer, an active layer, and a second conductivity type semiconductor layer, which are sequentially disposed on the intermediate layer,
wherein the intermediate layer comprises silicon nitride (SiN), and
wherein the feature pattern comprises at least one of silicon oxide (SiOₓ), silicon oxynitride (SiOₓN_{y}), and magnesium fluoride (MgF₂).

15. The semiconductor light-emitting device of claim 14, wherein the intermediate layer is conformally disposed on an upper surface of the substrate and on side surfaces and upper surfaces of the plurality of protrusions.

16. The semiconductor light-emitting device of claim 14, wherein the intermediate layer has a thickness ranging from 1 angstrom (Å) to 1 nanometer (nm), and
wherein the buffer layer has a thickness ranging from 5 nm to 30 nm.

17. The semiconductor light-emitting device of claim 14, wherein the feature pattern comprises the second material with a lower refractive index than a refractive index of the first material of the substrate, and
wherein a refractive index of the feature pattern ranges from 1.0 to 1.7.

18. The semiconductor light-emitting device of claim 14, wherein the feature pattern has at least one of a hemispherical shape or a cone shape.

19. A semiconductor light-emitting device, comprising:
a substrate comprising a first material;
a plurality of protrusions, each protrusion of the plurality of protrusions comprising:
a lower pattern comprising a same material as the first material of the substrate; and
a feature pattern on the lower pattern and comprising a second material different from the first material of the substrate;
a buffer layer on the substrate and the plurality of protrusions;
an intermediate layer on the buffer layer; and
a light-emitting stacked body comprising a first conductivity type semiconductor layer, an active layer, and a second conductivity type semiconductor layer, which are sequentially disposed on the intermediate layer,
wherein the intermediate layer comprises silicon nitride (SiN),
wherein the buffer layer comprises at least one of aluminum nitride (AlN), gallium nitride (GaN), indium nitride (InN), indium gallium nitride (InGaN), aluminum gallium nitride (AlGaN), indium aluminum gallium nitride (InAlGaN), or aluminum indium nitride (AlInN),
wherein the feature pattern comprises at least one of silicon oxide (SiOₓ), silicon oxynitride (SiOₓN_{y}), or magnesium fluoride (MgF₂), and
wherein the plurality of protrusions are disposed in a hexagonal arrangement.

20. The semiconductor light-emitting device of claim 19, wherein the intermediate layer has a thickness ranging from 1 angstrom (Å) to 1 nanometer (nm), and
wherein the buffer layer has a thickness ranging from 5 nm to 30 nm.
